(19) United States
(12) Patent Application Publication
(10) Pub. No.: US 2010/0064945 A1
(43) Pub. Date: Mar. 18, 2010

(54) Table With Solar Power Module

(75) Inventor: Ralf Sierenberg, Biedenkopf (DE)

Correspondence Address: KEN BURRASTON;KIRTON & MCCONKIE, PO BOX 45120, SALT LAKE CITY, UT, 84145-0120, US

(73) Assignee: GOLDEN SUN SOLAR LIGHTING AND TCHNOLGOY CO. LTD

(21) Appl. No.: 12/474,969

(22) Filed: May 29, 2009

Related U.S. Application Data
(60) Provisional application No. 61/057,545, filed on May 30, 2008.

(51) Int. Cl. A47B 37/00; H01L 31/042; A47B 3/00; A47B 13/08; A47B 13/12

(52) U.S. Cl. 108/50.02; 136/244

(57) ABSTRACT

A table can include a surface structure supportable by at least one leg component. A solar module can be operatively coupled to said surface structure and capable of receiving photonic energy impinging upon an upper surface of said table.

This application is a non-provisional of U.S. Provisional Patent Application Ser. No. 61/057,545, filed on May 30, 2008, which is hereby incorporated by reference.

### BACKGROUND

Solar energy is a clean, renewable, environmentally friendly source of energy that has been increasingly used in recent years. Embodiments of the present invention include a table incorporating a solar energy source by which power for an electrical device can be provided. Embodiments of the invention can allow for conversion and storage of the solar energy. Embodiments of the invention can also allow for convenient storage and transportation of the product.

### BRIEF DESCRIPTION OF THE DRAWINGS

FIG. 1 shows an exemplary solar powered table product according to some embodiments of the invention.

FIG. 2 shows a cross-sectional side view of the product of FIG. 1.

FIG. 3 shows a simplified block diagram of a circuit that can be located within a portion of the product of FIGS. 1 and 2.

### DETAILED DESCRIPTION OF EXEMPLARY EMBODIMENTS

This specification describes exemplary embodiments and applications of the invention. The invention, however, is not limited to these exemplary embodiments and applications or to the manner in which the exemplary embodiments and applications operate or are described herein. Moreover, the Figures may show simplified or partial views, and the dimensions of elements in the Figures may be exaggerated or otherwise not in proportion for clarity. In addition, as the terms “on” and “attached to” are used herein, one object (e.g., a material, a layer, a substrate, etc.) can be “on” or “attached to” another object regardless of whether the one object is directly on or attached to the other object or there are one or more intervening objects between the one object and the other object. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

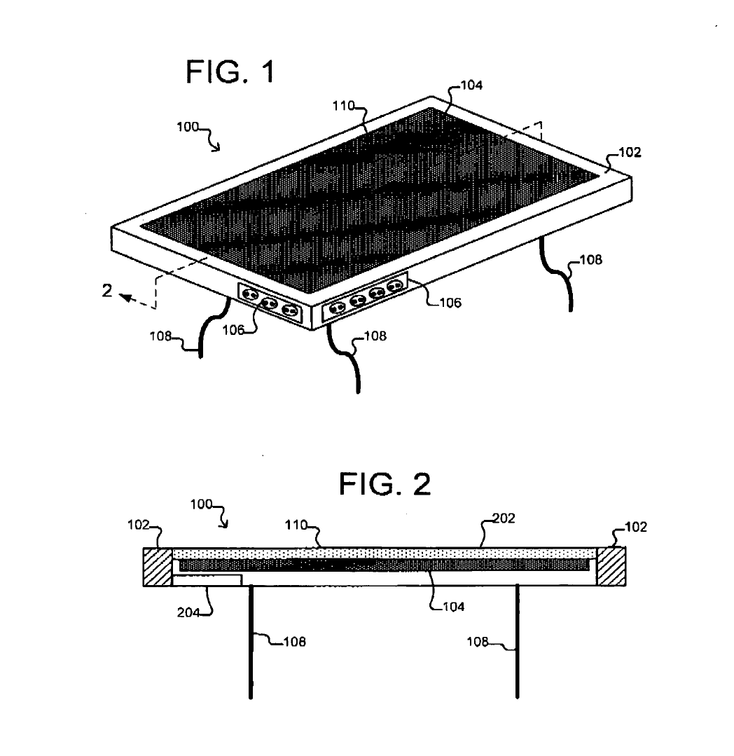

Referring to FIG. 1, a perspective view of an exemplary solar powered table 100 is illustrated. The solar powered table 100 can include a frame 102, a surface structure 110, and leg components 108. The frame 102 can hold the surface structure 110, which can provide an upper surface, or a working surface, upon which various items may be placed and supported. The frame 102 and surface structure 110 can form a table top, which may be provided in multiple sections. For example, in one embodiment the table top comprises two halves that are hingedly attached, whereby a user may unfold the two halves to form the solar powered table 100. In another embodiment, the table top comprises two halves that are capable of being coupled to one another to form the solar powered table 100. In yet another embodiment, the table top comprises two halves that may be separated to receive additional table top pieces. As such, the length or width of the table top may be increased by the additional table top pieces.

A solar module 104 can be attached to the surface structure 110, the frame 102, and/or other elements of the table 100. The surface structure 110 can be transparent or semitransparent or otherwise configured to allow sunlight to strike the solar module 104, which can comprise a one or more solar panels that convert the sunlight into electrical energy. The solar module 104 may include any material or device capable of generating usable energy via the photovoltaic effect. For example, in some embodiments, the solar module 104 comprises one or more solar cells. The solar cells can comprise silicon and/or can be thin film solar cells. The surface structure 110 can be lacquer or hardened polymer material, such as a polyurethane top coating. In another embodiment, the surface structure 110 can be glass, such as tempered glass, or Plexiglas.

The solar module 104 can be coupled to the frame 102, surface structure 110, or other elements of the table 110 in any suitable manner. For example, in some embodiments, the solar module 104 is attached directly to the surface structure 110 with an adhesive. In another embodiment, the frame 102 can provide recesses (not shown) into which the solar module 104 and/or the surface structure 110 can fit.

The frame 102 can include one or more electrical outlets 106. Although shown on a side, outward-facing portion of frame 102, the outlets 106 may be provided at any location on the frame 102. For example, outlets 106 can be provided at other locations on the side, outward-facing portion of frame 102. As another example, outlets 106 can be provided on an upper portion of frame 102, on a lower portion (e.g., facing the ground on which leg components 108 are disposed) of frame 102, or on an inward-facing portion of frame 102. As still other alternatives, outlets 106 can be located on portions of table 100 other than frame 102. The outlets 106 may include any type of receptacle providing a place in the system where current can be taken to run electrical devices. For example, in one embodiment the outlet 106 comprises a female electrical connector having slots or holes which accept the pins or blades of power plugs inserted into them and deliver electricity to the plugs. The outlet 106 may comprise any configuration or standard applicable to the needs of the user and the electrical devices. In another embodiment, the outlet 106 comprises a plurality of receptacles situated so as to provide convenient access to the user. Although shown on sides of frame 102, outlets 106 can alternatively be located on an underside of the frame 102 such that the outlets 106. In another embodiment, a cover (not shown) can be provided for the outlets 106 so as to protect the outlets from the weather.

Leg components 108 can support the frame 102. For example, in one embodiment the frame 102 is supported by 4 or more leg components 108. In another embodiment, the frame 102 is supported by 3 leg components 108. In another embodiment, the frame 102 is supported by one or more leg components 108, wherein each leg component 108 is a pedestal. The leg components 108 may comprise a material appropriate to the needs of the table 100. For example, the leg components 108 may include materials such as metal, plastic, wood, glass, composite, and combinations thereof. In one embodiment, the leg components 108 comprise hollow metal tubing material. The leg components 108 may also be collapsible or capable of being retracted or removed. As such, the overall size of the table 100 may be reduced for ease of transportation and storage. In one embodiment, the leg components 108 are hingedly attached to the frame 102 whereby the leg components 108 may collapse inwardly towards the frame 102. In another embodiment, the leg components 108 may be removed from the frame 102. As such, the table 100 may be used without the leg components 108, or the frame 102 and the leg components 108 may be transported and stored separate from one another.

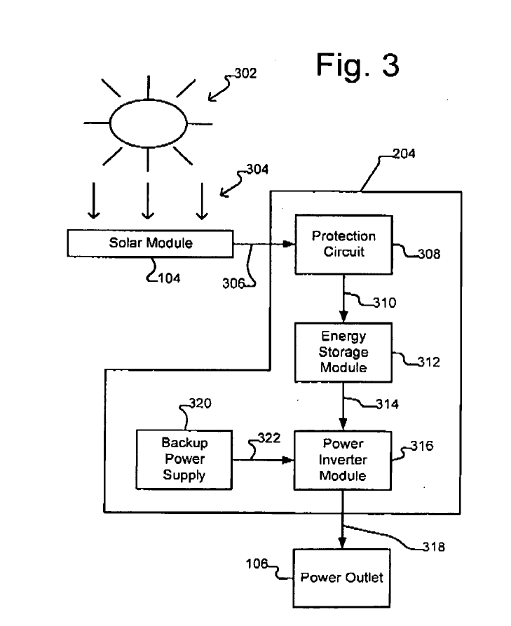

The solar powered table 100 further can comprise a power box 204. The power box 204 generally comprises circuitry and storage components for collecting and storing electrical energy produced by the solar module 104. FIG. 3 illustrates an exemplary configuration of solar module 104 and power box 204. As shown in FIG. 3, a solar module 104 can convert sunlight 302 into electricity using the photovoltaic effect. For example, photons 304 from the sunlight 302 contain various amounts of energy corresponding to the different wavelengths of light. When photons 304 strike the solar module 104, the photons 304 may be reflected or absorbed, or they may pass through the module 104. When photons 304 are absorbed, the energy of the photons 304 is transferred to electrons in an atom of the solar module 104, which produces electricity.

As shown in FIG. 3, the electricity produced by the solar module 104 can be output through a connector 306 to the power box 204. In some exemplary embodiments, the connector 306 can provide the electricity generated by the solar module 104 to a voltage protection circuit 308 within the power box 204. The voltage protection circuit 308 is generally provided to protect against supply voltage overloading. Supply voltage overloading typically occurs where spikes in voltage input exceed the systems ability to use and/or store the supplied voltage. As such, voltage overloading can lead to damage within the system 100. A protection circuit 308 can therefore be provided to prevent, or filter out excessive voltage thereby protecting the circuit. A suitable voltage protection circuit 308 may utilize varistors (VDR), zener diodes, and/or other overvoltage protection devices.

The power box 204 can further comprise a connector 310 for connecting the voltage protection circuit 308 to an energy storage module 312. The electricity generated by the solar module 104 can thus be provided to energy storage module 312, which can store the electricity generated by the solar module 104. The storage module 312 may include one or more cells or capacitors capable of storing the energy supplied from the solar module 104. For example, the storage module 312 may include one or more batteries. There are many types of batteries, including galvanic cells, electrolytic cells, fuel cells, flow cells, and voltaic piles, and any such battery can be used.

The power box 204 can further comprise a connector 314 for connecting the energy storage module 312 to a power inverter module 316. The power inverter module 316 can include a circuit for converting direct current (DC) from the storage module 312 to alternating current (AC). As such, the DC electricity from the storage module 312 can be used to operate AC equipment, such as those devices commonly plugged into household electrical receptacles. In one embodiment, the power inverter module 316 is provided to convert 12 volts DC to 120 volts AC. In another embodiment, the inverter module 316 is provided to convert 12 volts DC to 220 volts AC. Alternatively, the power inverter module 316 may be configured to step up, or step down the supplied voltage to a desired level. In some embodiments, the power inverter module 316 can be combined with a power regulator (not shown). The power regulator can be provided to step-down the voltage from the storage module 312. For example, in one embodiment the power regulator (not shown) is a step-down voltage regulator that drops the supplied voltage to 12 volts DC. Therefore, if the voltage supplied from the storage module 312 exceeds 12 volts DC, the power regulator limits the supplied voltage to 12 volts DC. In another embodiment, the power regulator is an adjustable step-down voltage regulator. As such, the power regulator may be adjusted to drop the supplied voltage to a range of voltages less than the supplied voltage. For example, in one embodiment the output voltage of the power regulator (not shown) can be adjusted from 2.8 volts DC to 26.5 volts DC.

In some embodiments, the power box 204 may include a connector 322 for connecting a backup power supply 320 to the power inverter module 316. The backup power supply 320 may provide an alternate source of energy during periods where the energy of the storage module 312 is depleted. For example, in situations where sunlight 302 is limited or unavailable, such as during overcast weather conditions or nighttime, lack of photons 304 may prevent energy production and storage. As such, the system 100 may be unable to power a desired electrical device. Therefore, a backup power supply 320 is provided. The backup power supply 320 may include a receptacle for attaching a generator or other similar electricity producing device. In one embodiment, the backup power supply 320 provides access to connect a car battery to the system 100.

The power box 204 can also comprise a connector 318 for connecting the power inverter module 316 to the power outlet 106. As previously discussed, the power outlet 106 may include any number of designs and configurations to accommodate the connectivity needs of a device. However, the power outlet 106 will generally comprise one or more female receptacles, such as those commonly used in household applications.

The embodiment of power box 204 shown in FIG. 3 is exemplary only and many variations are possible. For example, in some embodiments power box 204 may not include one or more of the backup power supply 320, power inverter module 316, and/or protection circuit 308. As another example, in some embodiments power box 204 can supply electricity generated by solar module 306 to power outlet 106 through one or more circuits not shown in FIG. 3.

Although specific embodiments and applications of the invention have been described in this specification, these embodiments and applications are exemplary only, and many variations are possible. For example, in some embodiments, the present invention may be retrofitted or adapted to an existing table surface. Alternatively, in some embodiments, the present invention may be incorporated into a picnic table or a patio table or an outdoor storage table (e.g., for storing boxes, crates, or other such items). Also, the table 100 can be made in many different sizes and shapes.

I claim:

1. A table comprising:
a surface structure;
at least one leg component operatively coupled to said surface structure; and
a solar module operatively coupled to said surface structure and capable of receiving photonic energy impinging upon an upper surface of said table;

2. The table of claim 1, further comprising:
a frame configured to hold said surface structure; and
an electrical outlet disposed in said frame and operatively coupled to said solar module to receive electrically energy from said solar module.

3. The table of claim 2, wherein said at least one leg component comprises a plurality of leg components hingeably coupled to said frame.

4. The table of claim 2, wherein said leg component is any one of collapsable, retractable, movable, and removable.

5. The table of claim 1, wherein said solar module is adhered to an upper surface of said surface structure.

6. The table of claim 1, wherein said solar module is disposed within a recess of said surface structure.

7. The table of claim 1, wherein the surface structure is transparent and said solar module is disposed beneath said surface structure.

8. The table of claim 1, further comprising a power module.

9. The table of claim 8, wherein the power module comprises a voltage protection circuit.

10. The table of claim 8, wherein the power module comprises a power inverter.

11. The table of claim 8, wherein the power module comprises a regulator.

12. The table of claim 8, wherein the power module comprises an energy storage module.

13. A method of using a solar powered table comprising:
configuring a solar powered table so that an upper surface of said solar powered table is exposed to a source of photonic energy;
converting said photonic energy into electrical energy using a solar module in said solar powered table;
operating an electrical device using said electrical energy.

14. The method of claim 13, further comprising storing said electrical energy in a storage module in said solar powered table.

15. The method of claim 13, further comprising converting said electrical energy using any one of a power inverter, a step up power regulator, and a step down power regulator.

16. The method of claim 13, wherein said configuring comprises unfolding hingedly coupled portions of said solar panel table.
